(19) United States
(12) Patent Application Publication
(10) Pub. No.: US 2025/0124977 A1
(43) Pub. Date: Apr. 17, 2025

(54) COMPILED MULTI-PORT MEMORY

(71) Applicant: Synopsys, Inc., Sunnyvale, CA (US)

(72) Inventor: John Edward BARTH, Williston, VT (US)

(21) Appl. No.: 18/379,957

(22) Filed: Oct. 13, 2023

(51) Int. Cl. G11C 11/419; G11C 11/412; H03K 19/20

(52) U.S. Cl. CPC G11C 11/419; G11C 11/412; H03K 19/20

(57) ABSTRACT

Certain aspects of the present disclosure are directed towards a multi-port memory cell. The multi-port memory cell may include: an inverter circuit cell; a hold circuit cell having an output coupled to an input of the inverter circuit cell and an input coupled to an output of the inverter circuit cell; and multiple unit circuit cells having respective tristate drivers, wherein a first plurality of the multiple unit circuit cells are configured as read circuit cells having inputs coupled to an output of the inverter circuit cell and a second plurality of the multiple unit circuit cells are configured as write circuit cells having outputs coupled to an input of the inverter circuit cell.

### TECHNICAL FIELD

The present disclosure generally relates to a memory architecture, and more particularly, to a multi-port memory.

### BACKGROUND

Memory plays an important role in electronic devices such as smartphones and computers. In some implementations, multi-port memory devices may be used which allow for more than one access port to a memory cell. For example, a multi-port memory may include multiple read ports and multiple write ports for a memory cell. Different circuits of a system may use the read ports to perform simultaneous read operations from the memory cell.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

Certain aspects of the present disclosure are directed towards a multi-port memory cell. The multi-port memory cell may include: an inverter circuit cell; a hold circuit cell having an output coupled to an input of the inverter circuit cell and an input coupled to an output of the inverter circuit cell; and multiple unit circuit cells having respective tristate drivers, wherein a first plurality of the multiple unit circuit cells are configured as read circuit cells having inputs coupled to an output of the inverter circuit cell and a second plurality of the multiple unit circuit cells are configured as write circuit cells having outputs coupled to an input of the inverter circuit cell.

Certain aspects of the present disclosure are directed towards a method for multi-port memory cell processing. The method generally includes: configuring a first plurality of multiple unit cells as read circuit cells by coupling inputs of the first plurality of the multiple unit circuit cells to an output of an inverter cell, the multiple unit circuit cells having respective tristate drivers; and configuring a second plurality of the multiple unit circuit cells as write circuit cells by coupling outputs of the second plurality of the multiple unit circuit cells to an input of the inverter circuit cell, wherein an output of a hold circuit cell is coupled to an input of the inverter circuit cell and an input of the hold circuit cell is coupled to an output of the inverter circuit cell.

Certain aspects of the present disclosure are directed towards an apparatus for multi-port memory cell processing. The apparatus generally includes a memory and one or more processors coupled to the memory, the one or more processors being configured to: configure a first plurality of multiple unit circuit cells as read circuit cells by coupling inputs of the first plurality of the multiple unit circuit cells to an output of an inverter circuit cell, the multiple unit circuit cells having respective tristate drivers; and configure a second plurality of the multiple unit circuit cells as write circuit cells by coupling outputs of the second plurality of the multiple unit circuit cells to an input of the inverter circuit cell, wherein an output of a hold circuit cell is coupled to an input of the inverter circuit cell and an input of the hold circuit cell is coupled to an output of the inverter circuit cell.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 illustrates an example memory cell of a static random access memory (SRAM).

FIG. 2A illustrates an example multi-port bit cell, including unit cells, in accordance with certain aspects of the present disclosure.

FIG. 2B illustrates an example unit cell, in accordance with certain aspects of the present disclosure.

FIGS. 3A, 3B, 3C, and 3D illustrate example implementations of tristate drivers.

FIG. 4 illustrates configurable multi-port memory implementations, in accordance with certain aspects of the present disclosure.

FIG. 5 illustrates a physical layout of a memory cell, in accordance with certain aspects of the present disclosure.

FIG. 6 illustrates a physical layout of a memory cell with a node mesh, in accordance with certain aspects of the present disclosure.

FIG. 7 illustrates a physical layout with a unit cell implemented as a read cell, in accordance with certain aspects of the present disclosure.

FIG. 8 illustrates a physical layout with a unit cell implemented as a write cell, in accordance with certain aspects of the present disclosure.

FIGS. 9 and 10 illustrate a wiring plan for a bit cell, in accordance with certain aspects of the present disclosure.

FIG. 11 is a flow diagram illustrating example operations for multi-port memory cell processing, in accordance with certain aspects of the present disclosure.

FIG. 12 illustrates an example set of processes used during the design, verification, and fabrication of an article of manufacture such as an integrated circuit to transform and verify design data and instructions that represent the integrated circuit.

FIG. 13 illustrates an example machine of a computer system within which a set of instructions, for causing the machine to perform any one or more of the methodologies discussed herein, may be executed.

### DETAILED DESCRIPTION

Certain aspects of the present disclosure are directed towards a configurable multi-port memory implementation. The memory may be implemented with an inverter circuit cell and a hold circuit cell. The output of the inverter cell may be coupled to an input of the hold cell and the input of the inverter cell may be coupled to an output of the hold cell. Thus, the inverter cell and the hold cell form a latch for the memory. The memory may also include multiple unit cells that may be configurable as either read or write cells. For example, each of the unit cells may include a tristate driver circuit. To configure a unit cell as a read cell, an input of the tristate driver may be coupled to an output of the inverter cell, and to configure a unit cell as a write cell, an output of the tristate driver may be coupled to an input of the inverter cell. Thus, a memory compiler may be used to configure any number of the unit cells as a read cell or a write cell by adjusting the coupling (e.g., wiring) of the inputs or outputs of the unit cells to the inverter cell. The aspects of the present disclosure provide one or more technical advantages such as reduced memory footprint. The memory architecture described herein (e.g., using tristate drivers) reduces the number of wires used to implement a multi-port memory, reducing the size of the memory, as described in more detail herein. Moreover, the present disclosure provides a multi-port memory with unit cells that can be efficiently configured as either read cells or write cells, providing processing efficiency, design simplicity, and reduced time to market for multi-port memories. For instance, based on user specifications, a memory compiler may configure a number of unit cells as read cells and a number of unit cells as write cells by adjusting the wiring for the unit cells as described herein.

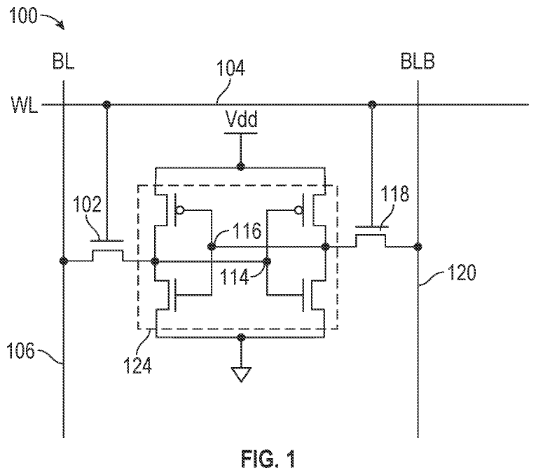

FIG. 1 illustrates an example memory cell 100 of a SRAM. As shown, the memory cell 100 may include a cross-coupled inverter pair 124 having an output 114 and an output 116. As shown, the cross-coupled inverter pair output 114 is selectively coupled to a bit-line (BL) 106 via a pass-gate transistor 102, and the cross-coupled inverter pair output 116 is selectively coupled to a complementary bit-line (BLB) 120 via a pass-gate transistor 118. The BL 106 and BLB 120 are configured to provide complementary digital signals to be written (e.g., stored) in the cross-coupled inverter pair 124. The BL and BLB may be used to store a bit in the memory cell 100. The gates of pass-gate transistors 102, 118 may be coupled to a word-line (WL) 104, as shown. For example, a digital signal to be written may be provided to the BL (and a complement of the digital signal is provided to the BLB). The pass-gate transistors 102, 118—which are implemented here as n-type field-effect transistors (NFETs)—are then turned on by providing a logic high signal to WL 104, resulting in the digital signal being stored in the cross-coupled inverter pair 124.

In some cases, a multi-port SRAM cell may be implemented. For example, the outputs 114, 116 may be selectively coupled to multiple read and write bitlines for implementing multiple read and write ports. For example, multiple read operations may be performed simultaneously from the cell. Applications for multi-ported memories include microprocessor caches, networking, artificial intelligence (AI) and machine learning, graph processing, deoxyribonucleic acid (DNA) alignment, and neuromorphic or brain-inspired applications. With increased activity in AI, high-order multi-port memories are becoming more popular.

Some multi-port cells may have numerous design issues, compounded by adding ports. Multi-port cells have problems associated with six-transistor (6T) SRAM cells (e.g., cell 100), such as read disturb and write failure, which are further complicated by asynchronous access patterns to multiple ports of the same memory cell. For example, two read operations to the same memory cell may occur simultaneously or be skewed slightly in time. The cells may need to respond in a manner that is covered by certain timing rules. Having to guard for all combinations and permutations of skewed accesses makes multi-port memories challenging to design, contributing to a long time to market. Furthermore, high order multi-port memories tend to be wire limited. That is, the main reason for the large size of multi-port memories is the number of wires that have to be routed for all the ports of the memory. Thus, reducing transistor count may not result in a shrinking of the cell size, and in fact, may result in an increase in the cell area as it may result in an increased number of wires having to be routed.

Certain aspects provide a compiled high-order multi-port (CHOMP) memory that may be implemented with two wires per port (e.g., a wire for a select line and a wire for a data line). The memory architecture described herein provides a robust and broken feedback architecture (e.g., where a feedback from a hold cell to an input of an inverter cell is broken to facilitate a write operation), allowing the memory to be implemented without read and write assist circuitry. Moreover, the memory described herein may be implemented without a bit-line pre-charge circuit and the associated timing specifications. The memory architecture may operate from a logic voltage domain (e.g., a supply voltage for logic circuits). The memory architecture may not use dual rail or level translators, making the memory relatively less complex. The memory architecture described herein provides design simplicity, lower memory footprint, and reduced time to market.

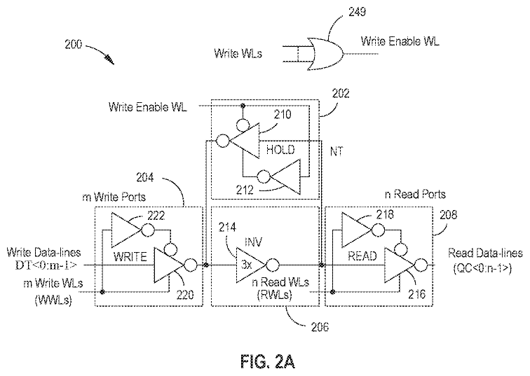

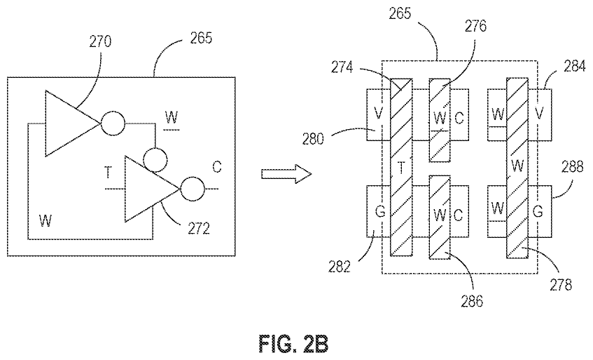

FIG. 2A illustrates an example multi-port bit cell 200, including unit cells, in accordance with certain aspects of the present disclosure. The bit cell 200 may include a memory element formed by cross-coupling an inverter 214 and a tristate feedback driver 210. The bit cell 200 includes an inverter cell 206 (e.g., including inverter 214) and a tristate cell 202 (e.g., including a tristate driver 210). The output of the tristate driver 210 may be coupled to an input of the inverter 214 and the output of the inverter 214 may be coupled to an input of the tristate driver 210, forming a latch.

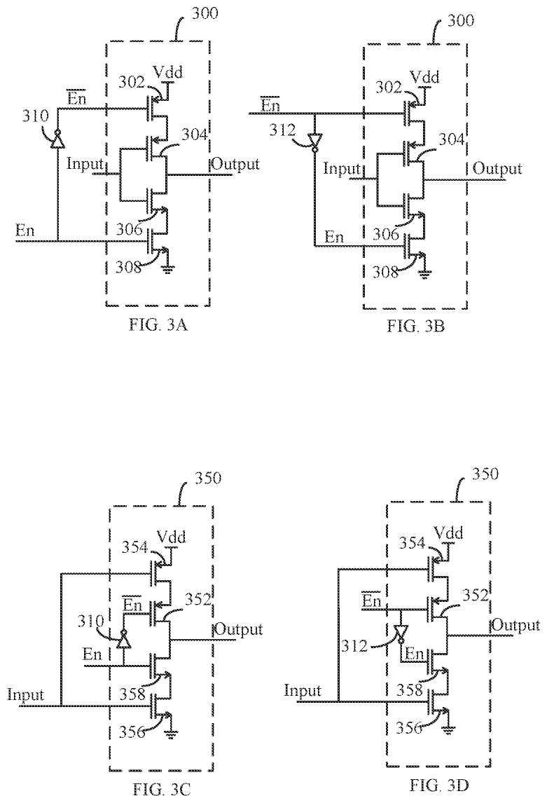

The tristate driver 210 (e.g., corresponding to tristate driver 300 with examples as described in FIGS. 3A-3D) may receive a complementary enable signal (e.g., from a write enable WL). The complementary enable signal may also be provided to an inverter 212 (e.g., corresponding to inverter 312 of FIG. 3) to generate an enable signal provided to the driver 210. Thus, the driver 210 may be enabled when the complementary enable signal at the write enable WL is logic low. While the driver 210 is enabled or disabled using a complementary enable signal (e.g., driver 210 is enabled when the complementary enable signal is logic low), an enable signal may be used in some implementations (e.g., driver 210 may be enabled when the enable signal is logic high).

The cell 200 may include m write cells 204, where m is a positive integer indicating a configurable quantity of the write ports. The cell 200 may also include n read cells, where n is a positive integer indicating the configurable quantity of read ports. Each of the write cells 204 includes a tristate driver 220. The write cells 204 are activated by respective m write wordlines (WWLs) to write data from the write datalines (DT<0 m-1>). Each of the write wordlines serves to enable a respective tristate driver 220. For example, a write wordline signal may be provided to the driver 220 as an enable signal and also provided to an inverter 222 to generate a complementary enable signal for the driver 220. As shown, the outputs of the write cells 204 (e.g., output of driver 220) may be coupled to an input of the inverter cell 206 (e.g., input of inverter 214). The output of the inverter cell 206 (e.g., output of inverter 214) may be coupled to inputs of read cells 208. The circuitry used to implement each of the read cells 208 may be the same as the circuitry used to implement each of the write cells 204. For example, each of the read cells 208 includes a tristate driver 216 having an input coupled to the output of the inverter cell 206. A read wordline signal may be provided to the driver 216 as an enable signal and also provided to an inverter 218 to generate a complementary enable signal for the driver 216.

In some aspects, when any of the write wordlines are activated, the write enable wordline controlling the tristate driver of the hold cell 202 is deactivated, breaking the feedback to the input of the inverter 214 and allowing a contention free write and avoiding an SRAM ratio issue (e.g., issues arising from ratios of strengths of pull up and pull down transistors of the SRAM cell). In other words, when enabled, the tristate driver 210 of the hold cell 202 holds the logic value of the memory cell using feedback from the output of the inverter 214 to the input of the inverter 214. When a new bit is to be written to the cell, the tristate driver 210 may be disabled (e.g., via the write enable WL), allowing the bit to be written to the cell 200.

As shown in FIG. 2A, the write WLs for the write cells may be coupled to input of an OR gate 249, where an output of the OR gate 249 is used as the write enable WL for the hold cell 202. That is, if any of the write WL signals transitions to logic high for a write operation, the write enable WL signal may transition to logic high, disabling the tristate driver 210 of the hold cell 202.

By using the same circuitry for the read and write cells, the read and write cells may be interchangeable, enabling memory configurability. In other words, the same cell may be used as either a read cell or a write cell depending on whether the input of the cell is coupled to the inverter cell 206 or the output of the cell is coupled to the inverter cell 206.

FIG. 2B illustrates an example unit cell 265 (e.g., corresponding to write cell 204 or read cell 208), in accordance with certain aspects of the present disclosure. The unit cell 265 may include tristate driver 272 (e.g., corresponding to driver 220 or 216) and an inverter 270 (e.g., corresponding to inverter 222 or 218). As shown, the unit cell 265 may include a gate region 274 (e.g., labelled “T” and corresponding to input of inverter 272) with portions disposed over respective portions of channels 280, 282. As shown, the unit cell 265 may include gate regions 276, 286, where portions of gate regions 276, 286 are disposed over portions of channels 280, 282, respectively. The gate region 276 may be used as a complementary enable (e.g., labelled “W” in FIG. 2B) for the driver 272 and the gate region 286 may be used as an enable (e.g., labelled “W” in FIG. 2B) for the driver 272. One end of channel 280 may be coupled to a voltage rail (e.g., Vdd, labelled “V” in FIG. 2B) and one end of channel 282 may be coupled to electric ground (e.g., labelled “G” in FIG. 2B). Other ends of the channel 280 may be coupled together and used as the output (e.g., labelled “C” in FIG. 2B) of the tristate driver 272. To implement the inverter 270, the unit cell 265 includes a gate region 278 (e.g., coupled to gate region 286 for the enable input) with portions disposed over respective portions channels 284, 288. As shown, one end of channel 284 may be coupled to the voltage rail (labelled “V”) and one end of the channel 288 may be coupled to electric ground (labelled “G”). Other ends of the channels 284, 288 may be coupled together and coupled to the complementary enable input (labeled “W”) of the driver 272.

FIGS. 3A and 3B illustrate an example implementation of a tristate driver 300 (e.g., corresponding to tristate driver 210). A tristate driver may include an input p-type metal-oxide-semiconductor (PMOS) transistor 304 and an input n-type metal-oxide-semiconductor (NMOS) transistor 306. The gates of transistors 304, 306 may be coupled to an input node of the tristate driver 300, as shown, where the drains of the transistors 304, 306 are coupled to an output node of the driver 300.

The driver 300 includes an enable PMOS transistor 302 having a drain coupled to a source of the transistor 304 and a source coupled to a voltage rail Vdd. The driver 300 also includes an enable NMOS transistor 308 having a drain coupled to a source of the transistor 306 and a source coupled to a reference potential node (e.g., electric ground). The gates of the transistors 302, 308 may be controlled to enable the tristate driver 300. For example, when the gate of transistor 302 is driven by a logic low signal and the gate of transistor 308 is driven by a logic high signal, the tristate driver is enabled. When enabled, the output signal of the driver 300 is equal to the inverse of the input signal of the driver 300. When the gate of transistor 302 is driven by a logic high signal and the gate of transistor 308 is driven by a logic low signal, the tristate driver is disabled. When disabled, the output of the driver 300 is in a high-impedance state. The gate of transistor 308 may be driven by an enable signal (En), and the gate of transistor 302 may be driven by a complementary enable signal (E̅n̅). As shown in FIG. 3A, the enable signal may be provided to a gate of transistor 308 and to an input of an inverter 310 (e.g., corresponding to inverter 218 or inverter 222) to generate the complementary enable signal at the gate of transistor 302. In some aspects, as shown in FIG. 3B, the complementary enable signal may be provided to a gate of transistor 302 and to an input of an inverter 312 (e.g., corresponding to inverter 212) to generate the enable signal at the gate of transistor 308. For example, the complementary enable signal may correspond to the write enable WL signal used to enable or disable the tristate driver 210.

FIGS. 3C and 3D illustrate another example implementation of a tristate driver 350 (e.g., corresponding to tristate driver 210). The tristate driver may include an input PMOS transistor 354 and an input NMOS transistor 356. The gates of transistors 354, 356 may be coupled to an input node of the tristate driver 350, as shown, where the drains of the transistors 354, 356 are coupled to respective sources of enable transistors 352, 358. The sources of transistors 354, 356 are coupled to a voltage rail Vdd and electric ground, respectively.

The drains of the enable transistors 352, 358 may be coupled to the output node of the driver 350. The gates of the transistors 352, 358 may be controlled to enable the tristate driver 350. For example, when the gate of transistor 352 is driven by a logic low signal and the gate of transistor 358 is driven by a logic high signal, the tristate driver is enabled. When enabled, the output signal of the driver 350 is equal to the inverse of the input signal of the driver 350. When the gate of transistor 352 is driven by a logic high signal and the gate of transistor 358 is driven by a logic low signal, the tristate driver is disabled. When disabled, the output of the driver 350 is in a high-impedance state. The gate of transistor 358 may be driven an enable signal (En), and the gate of transistor 352 may be driven by a complementary enable signal (E̅n̅). As shown in FIG. 3C, the enable signal may be provided to a gate of transistor 358 and to an input of an inverter 310 to generate the complementary enable signal at the gate of transistor 352. In some aspects, as shown in FIG. 3D, the complementary enable signal may be provided to a gate of transistor 352 and to an input of an inverter 312 to generate the enable signal at the gate of transistor 358.

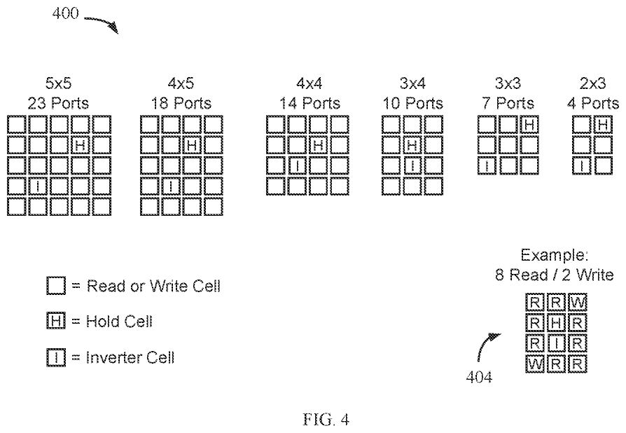

FIG. 4 illustrates configurable multi-port memory implementations 400, in accordance with certain aspects of the present disclosure. As shown, using a number of programmable read or write cells, a hold cell, and an inverter cell, a multi-port memory of any size may be implemented. For example, using 5×5 cells, a 23 port memory may be implemented, using 4×5 cells, an 18 port memory may be implemented, using a 4×4 cells, a 14 port memory may be implemented, using 3×4 cells, a 10 port memory may be implemented, using 3×3 cells, a 7 port memory may be implemented, and using 2×3 cells, a 4 port memory cell may be implemented. For instance, the 3×4 cell configuration 404 may include a hold cell (labelled “H”), an inverter cell (labelled “I”), 8 read cells (labelled “R”), and 2 write cells (labelled “W”), implementing a multi-port memory with 8 read ports and 2 write ports. The hold cell and the inverter cell form a latch for the memory cell. Each read or write cell may be programmed (e.g., wired) to be a read or a write port, offering a wide variety of read/write configurations.

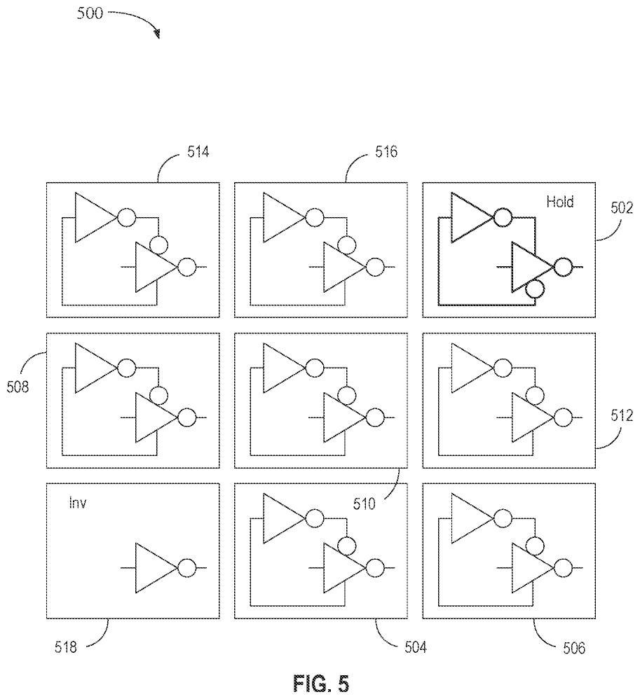

FIG. 5 illustrates a physical layout 500 of a 3×3 cell, in accordance with certain aspects of the present disclosure. As shown, the physical layout 500 includes a hold cell 502, an inverter cell 518, and multiple read or write cells 504, 506, 508, 510, 512, 514, 516.

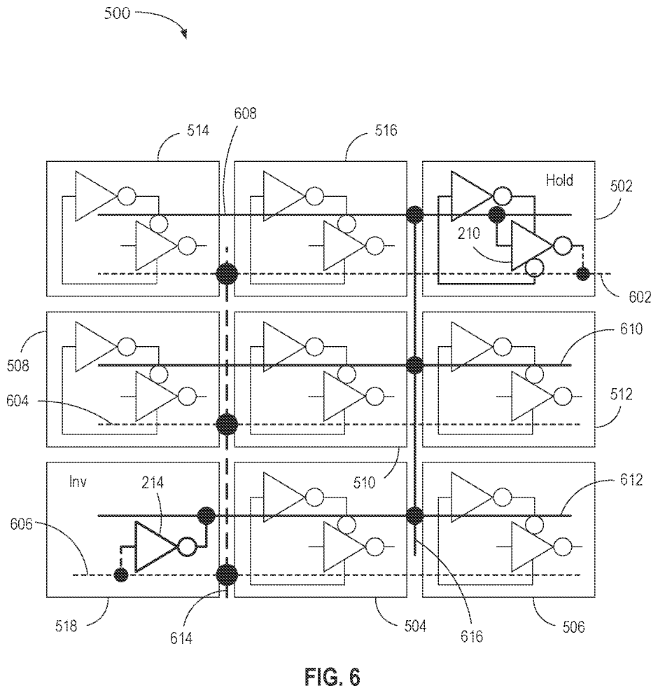

FIG. 6 illustrates the physical layout 500 with a node mesh, in accordance with certain aspects of the present disclosure. For example, the layout 500 includes traces 608, 610, 612 to implement a node (referred to herein as a true node) for the memory cell and traces 602, 604, 606 to implement a complementary node. The trace 614 is used to couple the traces 602, 604, 606 together and the trace 616 is used to couple the traces 608, 610, 612 together. As shown, the true node may be coupled to the output of inverter 214 and input of tristate driver 210 and the complementary node may be coupled to output of tristate driver 210 and the input of inverter 214, forming a latch for the memory cell.

The traces 602, 604, 606, 608, 610, 612 may be routed on a metal zero (M0) layer of a multi-layer substrate, and the traces 614, 616 may be routed on a metal one (M1) layer of the multi-layer substrate. The node mesh routes the true and complementary nodes to every unit cell so they can be used to program each unit cell to either a read or write port.

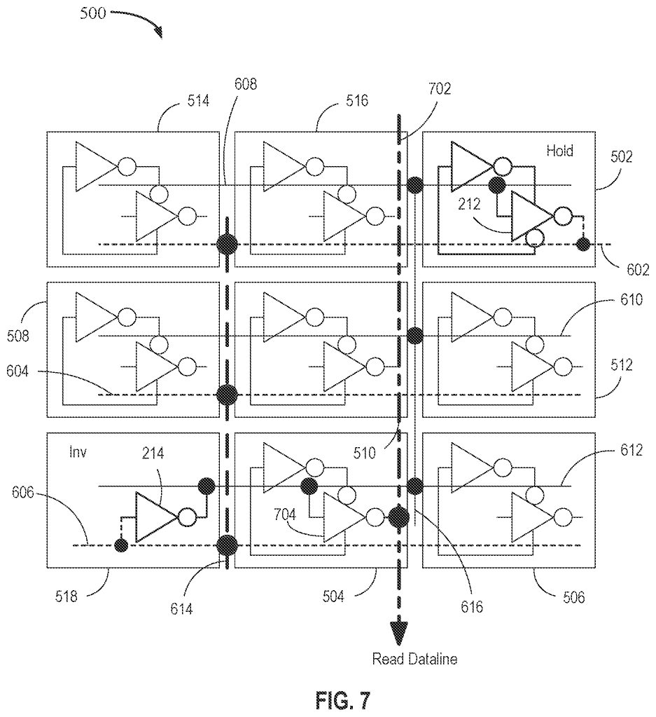

FIG. 7 illustrates the physical layout 500 with the cell 504 implemented as a read cell, in accordance with certain aspects of the present disclosure. As shown, the true node (e.g., trace 612) may be coupled to an input of tristate driver 704 (e.g., corresponding to tristate driver 216). Moreover, a trace for a read dataline 702 may be coupled to an output of the tristate driver 704.

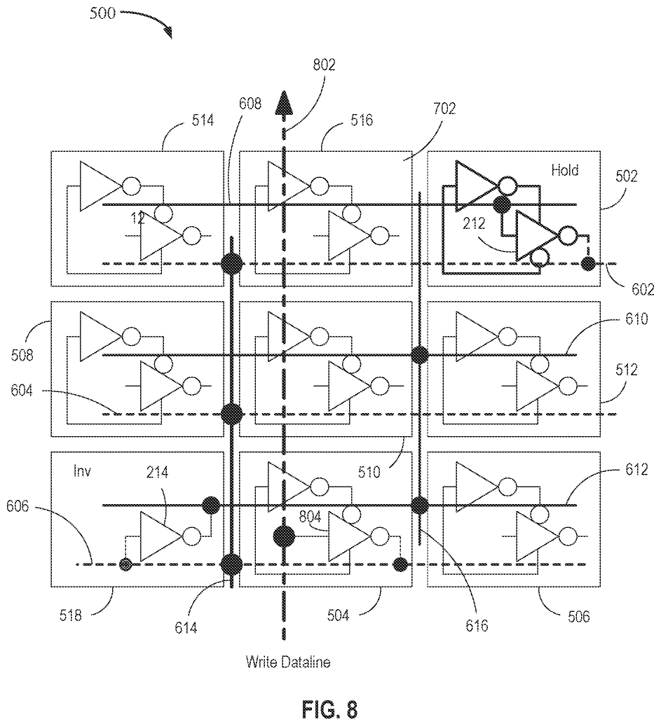

FIG. 8 illustrates the physical layout 500 with the cell 504 implemented as a write cell, in accordance with certain aspects of the present disclosure. As shown, the complementary node (e.g., trace 606) may be coupled to an output of tristate driver 804 (e.g., corresponding to tristate driver 220). Moreover, a trace for a write dataline 802 may be coupled to an input of the tristate driver 804. In this manner, each of the cells 504, 506, 508, 510, 512, 514, 516 may be configured as a read cell or a write cell.

As described herein, each cell may include a local inverter (e.g., inverter 222) with one trace (e.g., wire) per port. By adding the inverter for each cell, the number of traces (e.g., wires) may be reduced. Without the local inverter within each cell, three wires per port may be used (instead of 2), one for the write or read dataline, one for the enable signal, and one for the complementary enable signal. As shown by the layout in FIG. 2B, local inverter (e.g., inverter 270) and tristate driver (e.g., tristate driver 272) take four poly pitches and share power (e.g., Vdd) and ground, allowing each unit cell to be placed anywhere in the arrangement for the memory.

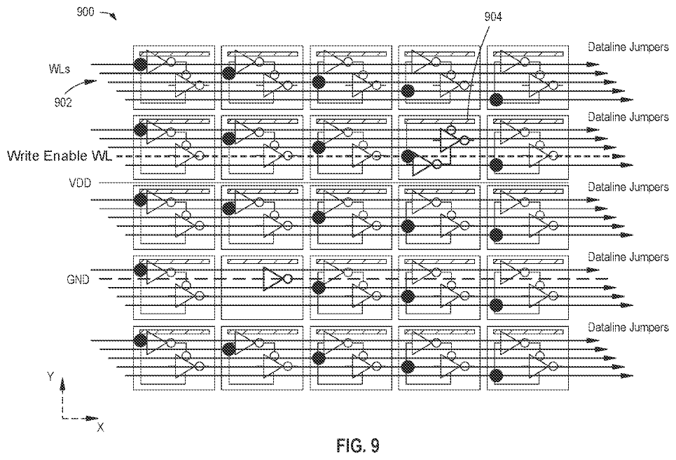

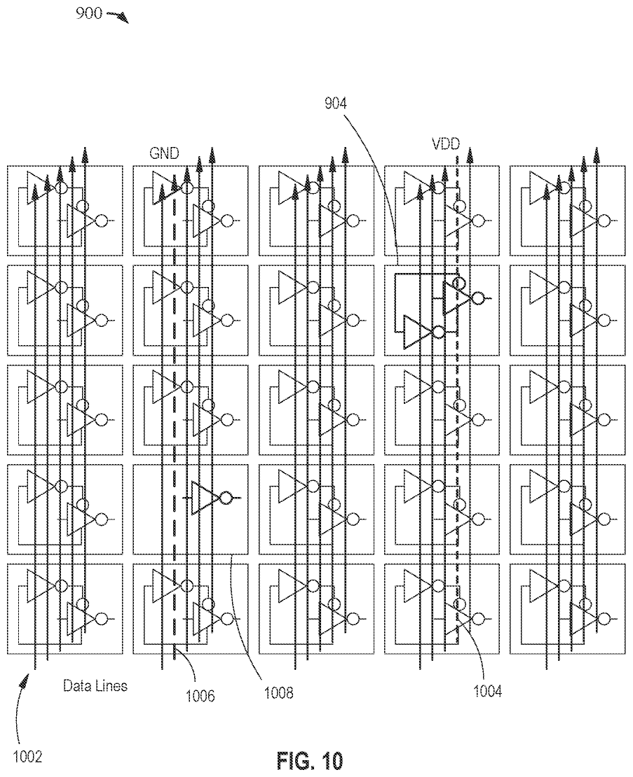

FIGS. 9 and 10 illustrate a wiring plan for a 5×5 bit cell 900, in accordance with certain aspects of the present disclosure. As shown, six traces 902 (e.g., on a metal two (M2) layer) may be used to support the five columns of unit cells. The number of wiring tracks limits the number of unit cells that can fit in the X dimension of the memory cell. The word lines (labeled “WLs” for the first row of cells) are routed across on the M2 layer, then coupled to each cell using vias. The word lines are pre-connected to each cell and can function as either a read wordline or a write wordline, determined by the unit cell programming as described herein.

As shown, a write enable wordline may be used to control the hold cell 904 and is activated when any one of the write wordlines (e.g., m write wordlines provided to driver 220) are activated, as described herein. A wiring track (e.g., labeled “Dataline Jumpers”) may be used per cell to provide a route for the data line (e.g., on metal three (M3) layer) down from the M3 layer through the M2 layer, down to the unit cell. As shown in FIG. 10, 23 datalines may be used for the bit cell 900. The datalines may be routed on the M3 layer, as described. For instance, five datalines 1002 may be routed for the five cells of the first columns. Each dataline may be routed over a respective unit cell of the first column and routed down to the unit cell on Ml layer using a via. Each dataline may be programmed as either a read dataline or write dataline, depending on the unit cell's programming. The number of unit cells for each column corresponds to the number of writing tracks that can be routed per cell. As shown, for the column that includes the hold cell 904, a voltage rail trace 1004 may be routed (e.g., in place of a dataline that would have otherwise been routed for a read or write cell), and for the column that includes the inverter cell 1008, a ground (GND) trace 1006 may be routed (e.g., in place of a dataline that would have otherwise been routed for a read or write cell).

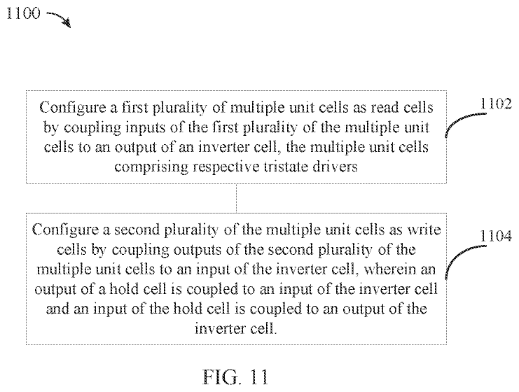

FIG. 11 is a flow diagram illustrating example operations 1100 for multi-port memory cell processing, in accordance with certain aspects of the present disclosure. The operations 1100 may be performed, for example, by a memory compiler, such as the memory compiler 1329.

At 1102, the compiler may configure a first plurality of multiple unit circuit cells (e.g., a first subset of unit cells 504, 506, 508, 510, 512, 514, 516 of FIG. 5) as read circuit cells by coupling inputs of the first plurality of the multiple unit circuit cells to an output of an inverter circuit cell (e.g., inverter cell 518), the multiple unit circuit cells comprising respective tristate drivers (e.g., tristate driver 216 or 220 shown in FIG. 2).

At 1104, the compiler may configure a second plurality of the multiple unit circuit cells (e.g., a second subset of unit cells 504, 506, 508, 510, 512, 514, 516 of FIG. 5) as write circuit cells by coupling outputs of the second plurality of the multiple unit circuit cells to an input of the inverter circuit cell. An output of a hold circuit cell (e.g., hold cell 502) may be coupled to an input of the inverter circuit cell and an input of the hold circuit cell may be coupled to an output of the inverter circuit cell. In some aspects, the hold circuit cell may include a tristate driver (e.g., tristate driver 210). The compiler may configure the tristate driver of the hold circuit cell to be disabled (e.g., via write enable WL shown in FIG. 2) based on one of the write circuit cells being enabled.

In some aspects, a first node may include a first plurality of traces (e.g., traces 608, 610, 612) may be routed adjacent to the multiple unit circuit cells. A second node including a second plurality of traces (e.g., traces 602, 604, 606) routed adjacent to the multiple unit circuit cells. In some aspects, to configure the first plurality of the multiple unit circuit cells as read cells, the compiler may couple the first node to an input of the tristate drivers (e.g., tristate driver 704 of FIG. 7) of the first plurality of the multiple unit circuit cells. To configure the second plurality of the multiple unit circuit cells as write circuit cells, the compiler may couple the second node to an output of the tristate drivers (e.g., tristate driver 804) of the second plurality of the multiple unit circuit cells.

In some aspects, to configuring the first plurality of the multiple unit circuit cells as read circuit cells, the compiler may couple a read dataline (e.g., read dataline 702 of FIG. 7) to an output of each of the tristate drivers of the first plurality of the multiple unit circuit cells. To configure the second plurality of the multiple unit circuit cells as write circuit cells, the compiler may couple a write dataline (e.g., write dataline 802) to an input of each of the tristate drivers of the second plurality of the multiple unit circuit cells. In some aspects, to configure the second plurality of the multiple unit circuit cells as write circuit cells, the compiler may couple wordlines to respective enable inputs of the tristate drivers of the second plurality of the multiple unit circuit cells. In some aspects, a tristate driver of the hold circuit cell may be configured to be disabled based on signals at the wordlines.

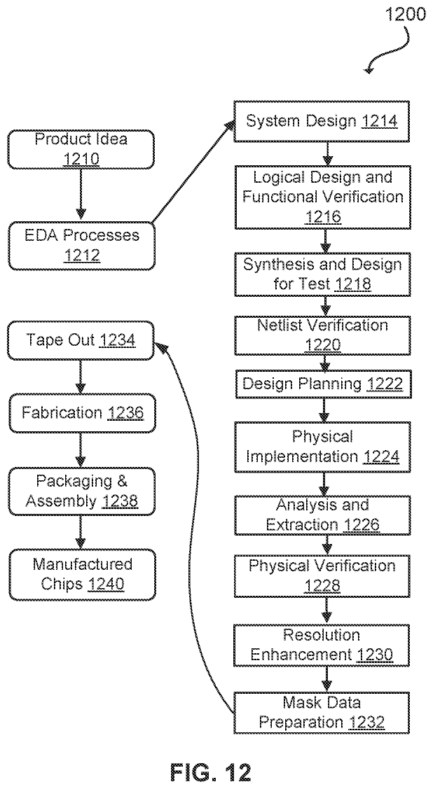

FIG. 12 illustrates an example set of processes 1200 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 1210 with information supplied by a designer, information which is transformed to create an article of manufacture that uses a set of EDA processes 1212. When the design is finalized, the design is taped-out 1234, which is when artwork (e.g., geometric patterns) for the integrated circuit is sent to a fabrication facility to manufacture the mask set, which is then used to manufacture the integrated circuit. After tape-out, a semiconductor die is fabricated 1236 and packaging and assembly processes 1238 are performed to produce the finished integrated circuit 1240.

Specifications for a circuit or electronic structure may range from low-level transistor material layouts to high-level description languages. A high-level representation may be used to design circuits and systems, using a hardware description language (‘HDL’) such as VHDL, Verilog, System Verilog, SystemC, MyHDL or OpenVera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding tools of that layer (e.g., a formal verification tool). A design process may use a sequence depicted in FIG. 12. The processes described by be enabled by EDA products (or tools).

During system design 1214, functionality of an integrated circuit to be manufactured is specified. For example, a compiler may be used to generate a design for a memory, as described herein. The design may be optimized for desired characteristics such as power consumption, performance, area (physical and/or lines of code), and reduction of costs, etc. Partitioning of the design into different types of modules or components can occur at this stage.

During logic design and functional verification 1216, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 1218, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 1220, the netlist is checked for compliance with timing constraints and for correspondence with the HDL code. During design planning 1222, an overall floor plan for the integrated circuit is constructed and analyzed for timing and top-level routing.

During layout or physical implementation 1224, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 1226, the circuit function is verified at the layout level, which permits refinement of the layout design. During physical verification 1228, the layout design is checked to ensure that manufacturing constraints are correct, such as DRC constraints, electrical constraints, lithographic constraints, and that circuitry function matches the HDL design specification. During resolution enhancement 1230, the geometry of the layout is transformed to improve how the circuit design is manufactured.

During tape-out, data is created to be used (after lithographic enhancements are applied if appropriate) for production of lithography masks. During mask data preparation 1232, the ‘tape-out’ data is used to produce lithography masks that are used to produce finished integrated circuits.

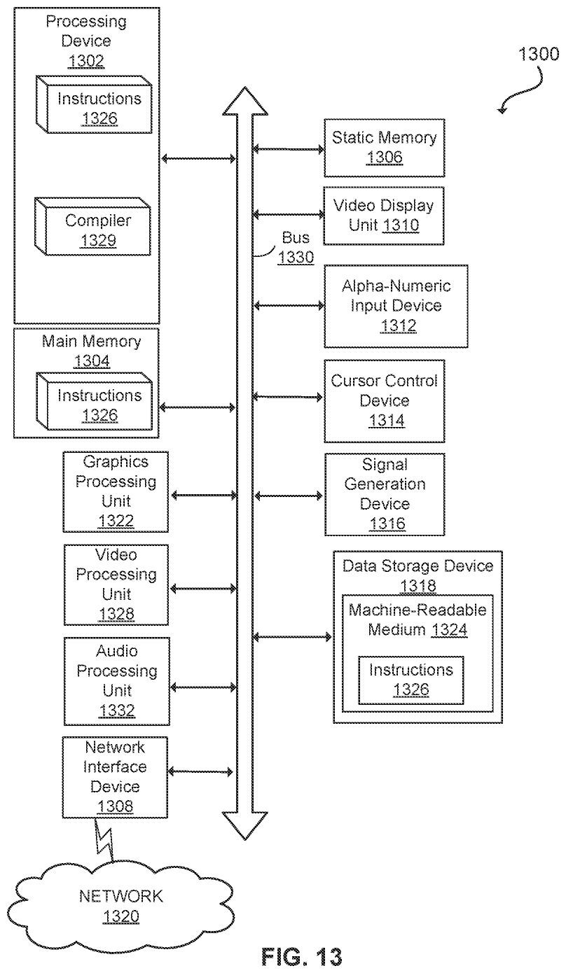

A storage subsystem of a computer system (such as computer system 1300 of FIG. 13) may be used to store the programs and data structures that are used by some or all of the EDA products described herein, and products used for development of cells for the library and for physical and logical design that use the library.

FIG. 13 illustrates an example machine of a computer system 1300 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1300 includes a processing device 1302, a main memory 1304 (e.g., read-only memory (ROM), flash memory, dynamic random access memory (DRAM) such as synchronous DRAM (SDRAM), a static memory 1306 (e.g., flash memory, static random access memory (SRAM), etc.), and a data storage device 1318, which communicate with each other via a bus 1330.

Processing device 1302 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1302 may also be one or more special-purpose processing devices such as an application specific integrated circuit (ASIC), a field programmable gate array (FPGA), a digital signal processor (DSP), network processor, or the like. The processing device 1302 may be configured to execute instructions 1326 for performing the operations and steps described herein.

The computer system 1300 may further include a network interface device 1308 to communicate over the network 1320. The computer system 1300 also may include a video display unit 1310 (e.g., a liquid crystal display (LCD) or a cathode ray tube (CRT)), an alphanumeric input device 1312 (e.g., a keyboard), a cursor control device 1314 (e.g., a mouse), a graphics processing unit 1322, a signal generation device 1316 (e.g., a speaker), graphics processing unit 1322, video processing unit 1328, and audio processing unit 1332.

The data storage device 1318 may include a machine-readable storage medium 1324 (also known as a non-transitory computer-readable medium) on which is stored one or more sets of instructions 1326 or software embodying any one or more of the methodologies or functions described herein. The instructions 1326 may also reside, completely or at least partially, within the main memory 1304 and/or within the processing device 1302 during execution thereof by the computer system 1300, the main memory 1304 and the processing device 1302 also constituting machine-readable storage media.

In some implementations, the instructions 1326 include instructions to implement functionality corresponding to the present disclosure. While the machine-readable storage medium 1324 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 1302 to perform any one or more of the methodologies of the present disclosure. The term “machine-readable storage medium” shall accordingly be taken to include, but not be limited to, solid-state memories, optical media, and magnetic media.

In some aspects of the present disclosure, the processing device 1302 may include a memory compiler 1329. The memory compiler 1329 may generate a representation of a memory in accordance with certain aspects of the present disclosure.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A multi-port memory cell, comprising:
an inverter circuit cell;
a hold circuit cell having an output coupled to an input of the inverter circuit cell and an input coupled to an output of the inverter circuit cell; and
multiple unit circuit cells having respective tristate drivers, wherein a first plurality of the multiple unit circuit cells are configured as read circuit cells having inputs coupled to the output of the inverter circuit cell and a second plurality of the multiple unit circuit cells are configured as write circuit cells having outputs coupled to an input of the inverter circuit cell.

2. The multi-port memory cell of claim 1, wherein the hold circuit cell comprises a tristate driver.

3. The multi-port memory cell of claim 2, wherein the tristate driver of the hold circuit cell is disabled when one of the write circuit cells is enabled.

4. The multi-port memory cell of claim 2, wherein the hold circuit cell further comprises an inverter coupled between an enable input and a complementary enable input of the tristate driver of the hold circuit cell.

5. The multi-port memory cell of claim 1, wherein each of the multiple unit circuit cells comprises an inverter coupled between an enable input and a complementary enable input of a respective one of the tristate drivers.

6. The multi-port memory cell of claim 1, further comprising:
a first node including a first plurality of traces routed adjacent to the multiple unit circuit cells; and
a second node including a second plurality of traces routed adjacent to the multiple unit circuit cells, wherein the second node is configured to route a signal that is complementary to a signal routed by the first node.

7. The multi-port memory cell of claim 6, wherein the first plurality of the multiple unit circuit cells are configured as read cells by coupling the first node to an input of the tristate drivers of the first plurality of the multiple unit circuit cells.

8. The multi-port memory cell of claim 6, wherein the second plurality of the multiple unit circuit cells are configured as write cells by coupling the second node to an output of the tristate drivers of the second plurality of the multiple unit circuit cells.

9. The multi-port memory cell of claim 1, wherein the first plurality of the multiple unit circuit cells are configured as read cells by coupling a read dataline to an output of each of the tristate drivers of the first plurality of the multiple unit circuit cells.

10. The multi-port memory cell of claim 1, wherein the second plurality of the multiple unit circuit cells are configured as write circuit cells by coupling a write dataline to an input of each of the tristate drivers of the second plurality of the multiple unit circuit cells.

11. The multi-port memory cell of claim 1, wherein the second plurality of the multiple unit circuit cells are configured as write cells by coupling wordlines to respective enable inputs of the tristate drivers of the second plurality of the multiple unit circuit cells.

12. The multi-port memory cell of claim 11, further comprising an OR gate, wherein the wordlines are further coupled to inputs of the OR gate, and wherein an output of the OR gate is coupled to an enable input of the hold circuit cell.

13. A method for multi-port memory cell processing, comprising:
configuring a first plurality of multiple unit circuit cells as read circuit cells by coupling inputs of the first plurality of the multiple unit circuit cells to an output of an inverter circuit cell, the multiple unit circuit cells comprising respective tristate drivers; and
configuring a second plurality of the multiple unit circuit cells as write cells by coupling outputs of the second plurality of the multiple unit circuit cells to an input of the inverter circuit cell, wherein an output of a hold circuit cell is coupled to an input of the inverter circuit cell and an input of the hold circuit cell is coupled to an output of the inverter circuit cell.

14. The method of claim 13, wherein the hold circuit cell comprises a tristate driver.

15. The method of claim 14, further comprising configuring the tristate driver of the hold circuit cell to be disabled based on one of the write cells being enabled.

16. The method of claim 13, wherein:
a first node including a first plurality of traces routed adjacent to the multiple unit circuit cells; and
a second node including a second plurality of traces routed adjacent to the multiple unit circuit cells;
configuring the first plurality of the multiple unit circuit cells as read circuit cells includes coupling the first node to an input of the tristate drivers of the first plurality of the multiple unit circuit cells; and
configuring the second plurality of the multiple unit circuit cells as write circuit cells includes coupling the second node to an output of the tristate drivers of the second plurality of the multiple unit circuit cells.

17. The method of claim 13, wherein configuring the first plurality of the multiple unit circuit cells as read circuit cells includes coupling a read dataline to an output of each of the tristate drivers of the first plurality of the multiple unit circuit cells.

18. The method of claim 13, wherein configuring the second plurality of the multiple unit circuit cells as write circuit cells includes coupling a write dataline to an input of each of the tristate drivers of the second plurality of the multiple unit circuit cells.

19. The method of claim 13, wherein:
configuring the second plurality of the multiple unit circuit cells as write circuit cells includes coupling wordlines to respective enable inputs of the tristate drivers of the second plurality of the multiple unit circuit cells; and
a tristate driver of the hold circuit cell is configured to be disabled based on signals at the wordlines.

20. An apparatus for multi-port memory cell processing, comprising:
a memory; and
one or more processors coupled to the memory, the one or more processors being configured to:
configure a first plurality of multiple unit circuit cells as read circuit cells by coupling inputs of the first plurality of the multiple unit circuit cells to an output of an inverter circuit cell, the multiple unit circuit cells comprising respective tristate drivers; and
configure a second plurality of the multiple unit circuit cells as write cells by coupling outputs of the second plurality of the multiple unit circuit cells to an input of the inverter circuit cell, wherein an output of a hold circuit cell is coupled to an input of the inverter circuit cell and an input of the hold circuit cell is coupled to an output of the inverter circuit cell.
